(19) United States
(12) Patent Application Publication
(10) Pub. No.: US 2004/0150955 A1
(43) Pub. Date: Aug. 5, 2004

(54) Connecting apparatus of one single radiation plate

(76) Inventor: You-Tien Lin, Hsing-Chuang City (TW)

Correspondence Address: You-Tien Lin, P. O. Box 1-252, Sanchung City, TW

(21) Appl. No.: 10/357,036

(22) Filed: Jan. 31, 2003

(51) Int. Cl. H05K 7/20

(52) U.S. Cl. 361/709

(57) ABSTRACT

The invention is related to a connecting apparatus of one single radiation plate which comprises an L-shaped plate body, wherein the plate body has disposed two or more connecting apparatuses at the both sides of the upper end and lower end respectively or further disposed at the both sides of the middle section thereof. Each connecting apparatus at the upper end of the plate body includes a hook protruding from a short folding edge on the tope of the plate body and a semicircular aperture on the joint of the short folding edge and the plate body. Each connecting apparatus below includes a hook extending from a long level folding edge at the bottom of the plate body and a semicircular aperture on the joint between the L-shaped plate body and the long level folding edge. Alternatively, each of the upper connecting apparatuses consists of an ascending-stepped strip wherein the both sides of the forward part or the either side thereof is folded downward to constitute two or one hook section on an outward slant; the left or right bottom of the plate body is folded into a descending-stepped strip wherein the both sides of the forward part or the either side thereof is folded upward to form two or one hook section on an outward slant. To assemble a number of single radiation plates of the present invention in parallel for integrating into a heat sink, each hook or hook section at the upper and bottom ends of the preceding plate is fastened with the corresponding aperture or strip of the other radiation plate to the effect that every two radiation plates are firmly linked with each other.

### BACKGROUND OF THE INVENTION

1) Field of the Invention

The present invention relates to a connecting apparatus of one single radiation plate and particularly to a connecting device of which the manufacturing process and assemblage are much more convenient than ever before. This invention is also characterized by simple structure and excellent fastening ability to connect a number of radiation plates in parallel into a fin heat sink in different length or dimension.

2) Description of the Prior Art

A conventional heat sink is either made of aluminum by the method of extrusion- or die casting into an integral forming product or it is made by the method that a spiral aluminum belt coils around the outer periphery of aluminum pipe (or copper pipe.) However, the above processing methods are carried out by multiple complicated procedures or require attaching other matching components that result in significant expense and inconvenience of installation.

Recently, some company produced a fin heat sink with connecting device thereof which is capable of manufacturing by simplified procedures to thereby reduce its manufacturing cost and improve inconvenience of installation. However, the said connecting device is composed of a protuberance and a concave for inter-linkage or it is comprised of a hook and a slot wherein each hook is interlocked with the corresponding slot to constitute a fin heat sink; however, the hook is not firmly linked with the slot so that detachment, breakage or damage occurs readily. Therefore, the said connecting device is unable to fulfill durable demand; in view of the above drawbacks, the applicant improved the connecting device and then conducted research and testing that culminated in the innovative development of the invention herein.

### SUMMARY OF THE INVENTION

The objective of the invention herein is to provide a connecting apparatus of one single radiation plate with the characteristics of easy assemblage and superior fastening capability, which is made by means of continuous molds and dies in a process of integrated operation to produce a great quantity of radiation plates within a short time, thereby reducing the manufacturing cost. A small amount of radiation plates or more are easily assembled in parallel into a fin heat sink in various size or length to meet customers' needs and requirements.

The brief description of the drawings below is followed by the detailed description of the invention.

### BRIEF DESCRIPTION OF THE DRAWINGS

FIG. 1 is an elevation of one single radiation plate as a better embodiment of the present invention;

FIG. 1˜1 is an elevation of another example of FIG. 1;

FIG. 2 is an elevation of two radiation plates as depicted in FIG. 1 to show the status of parallel connection;

FIG. 3 is an enlarged view showing one upper connecting apparatus on the radiation plate of FIG. 1;

FIG. 4 is an enlarged view showing a lower connecting apparatus on the radiation plate of FIG. 1;

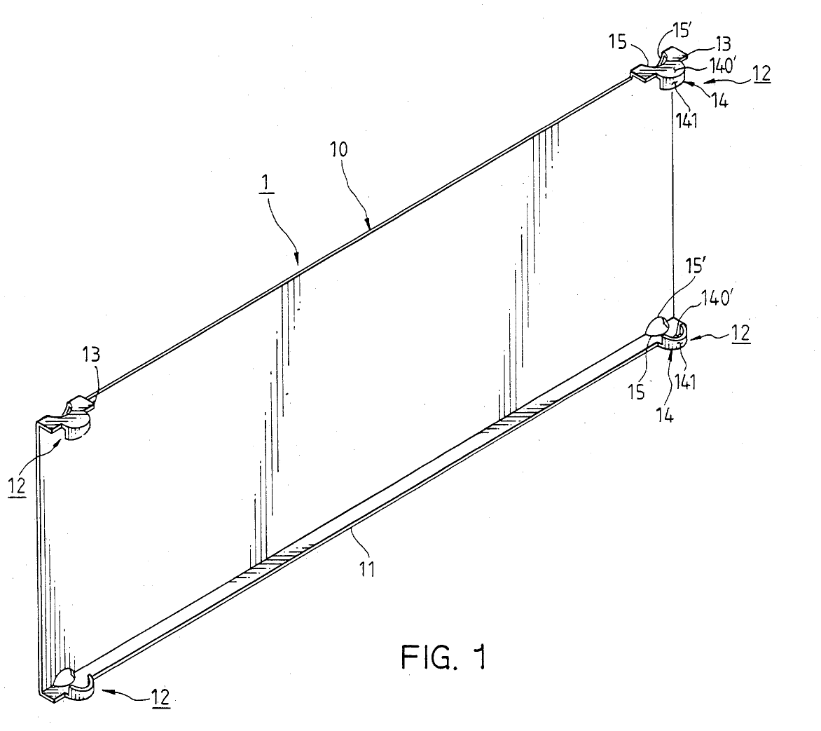

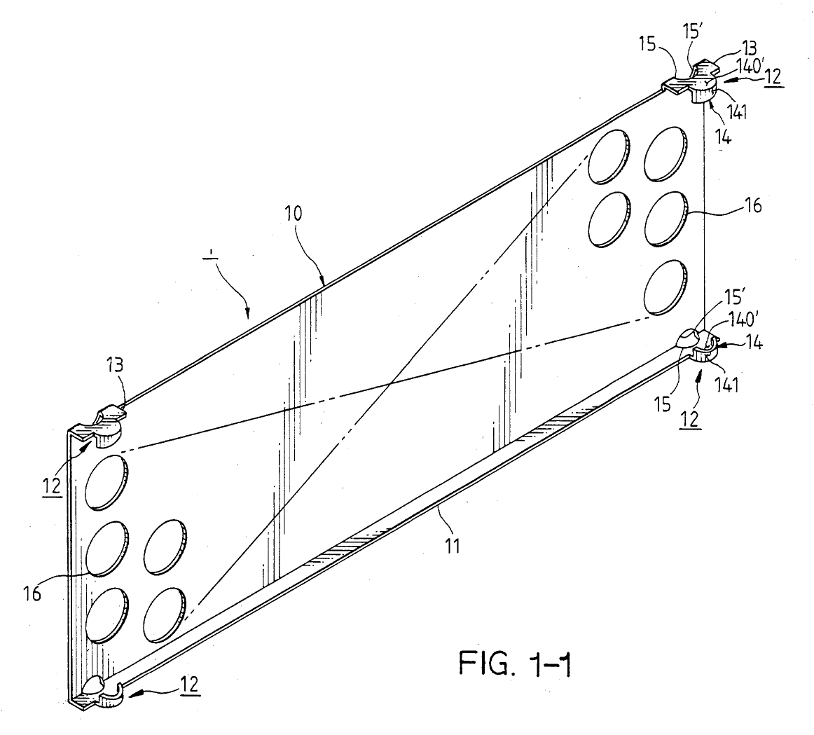

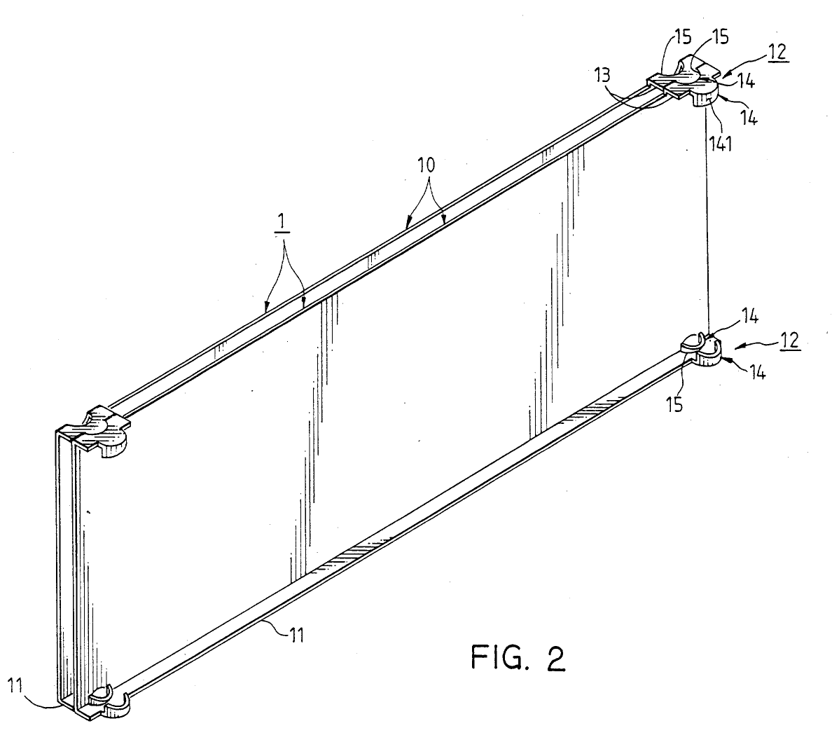

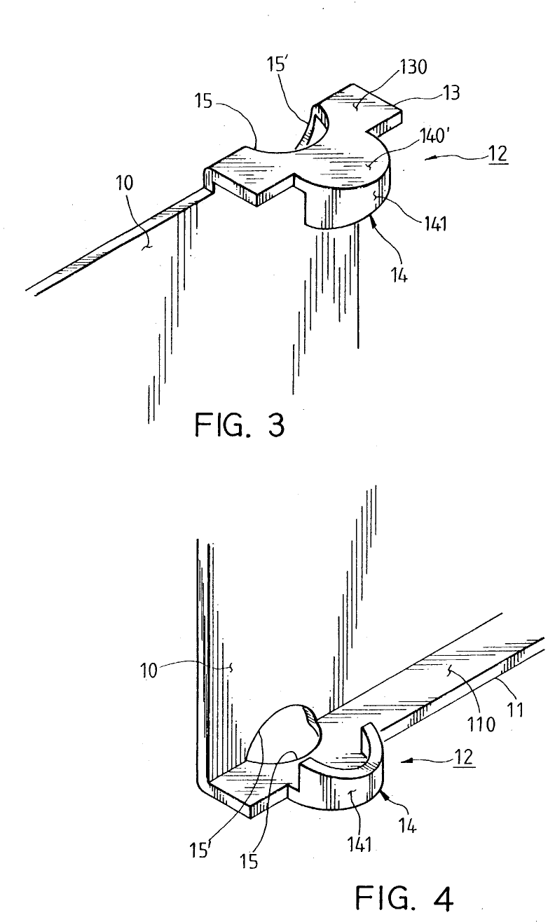

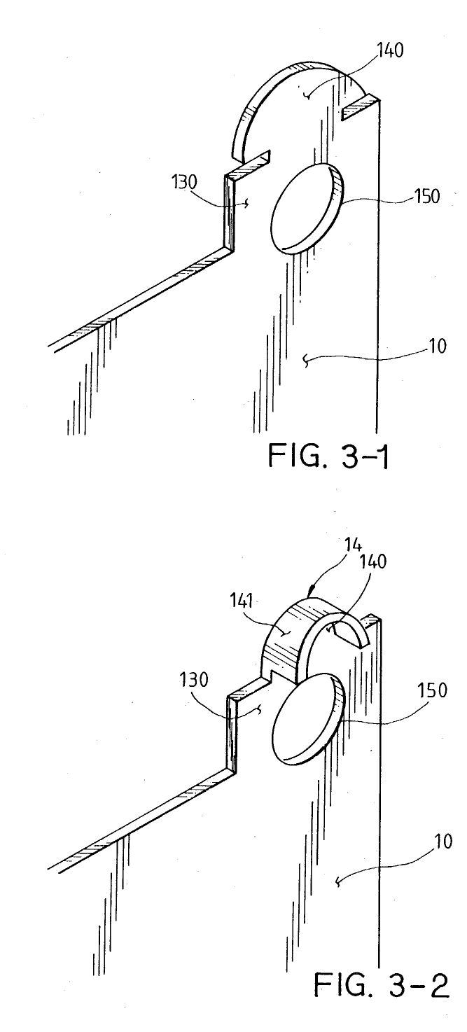

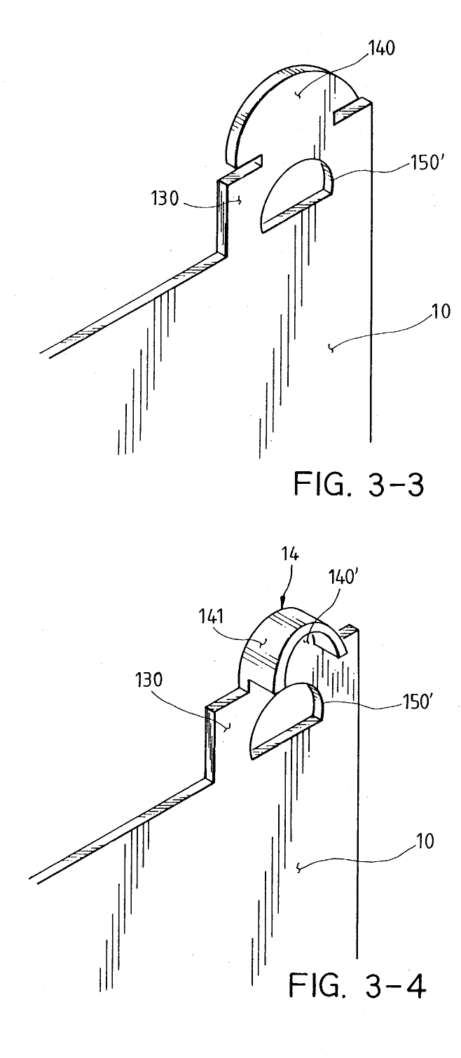

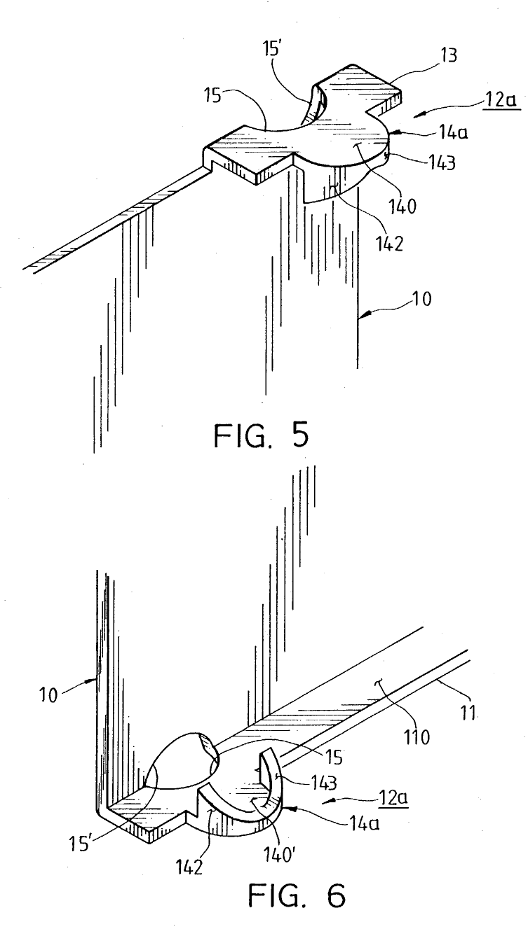

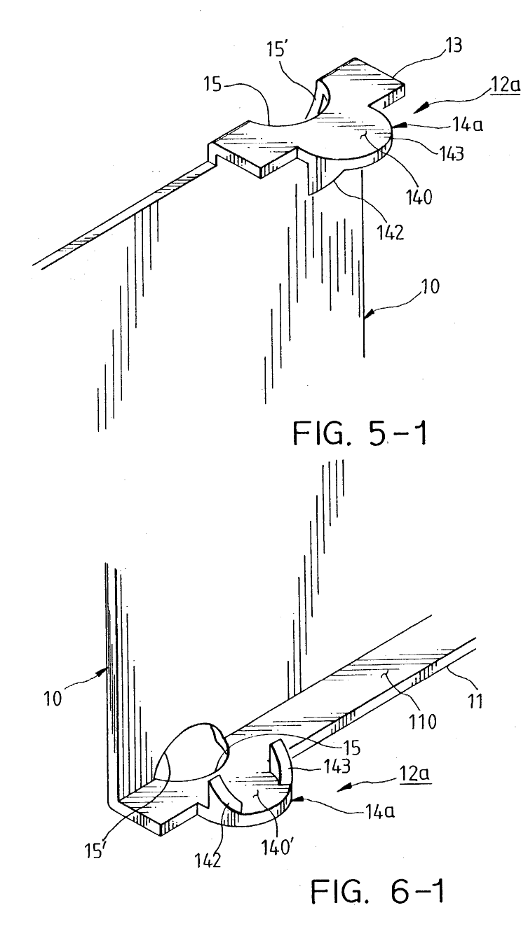

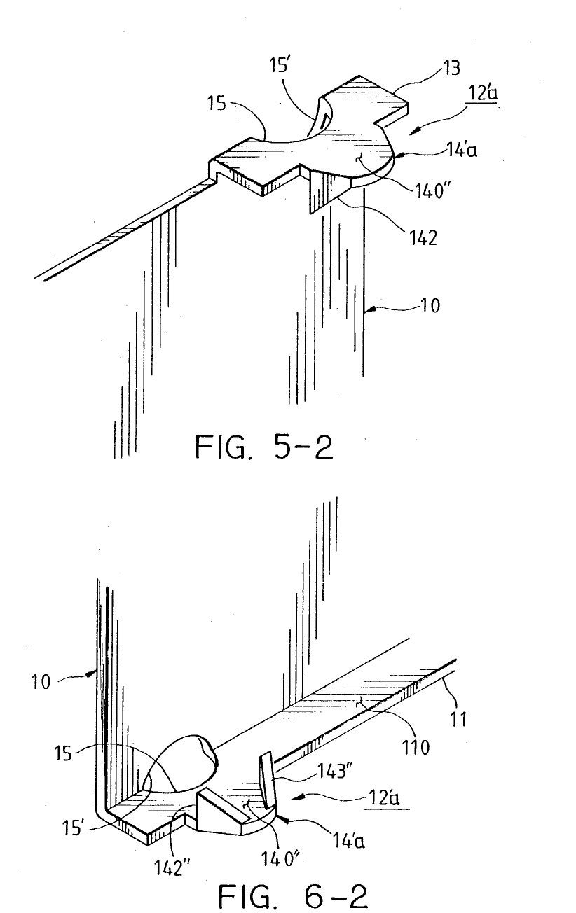

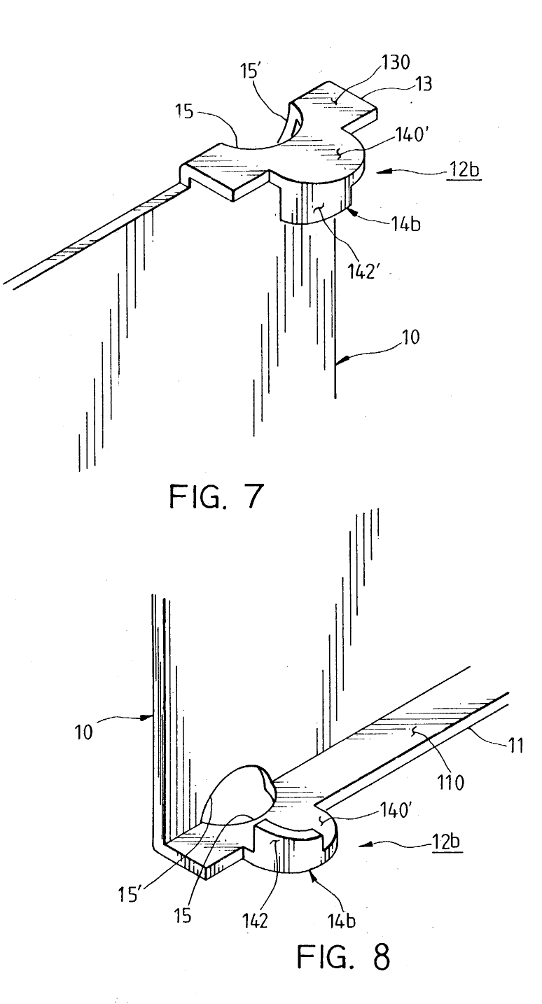

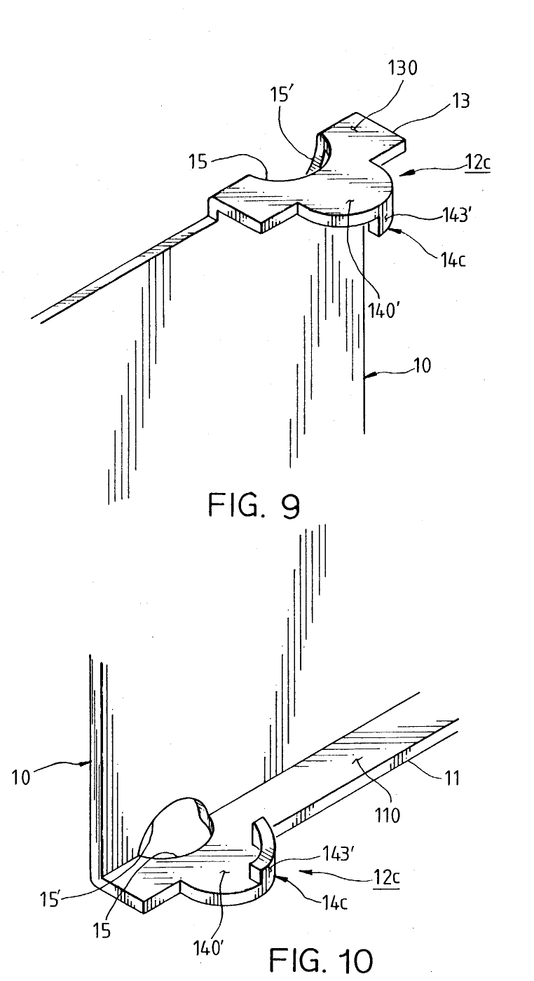

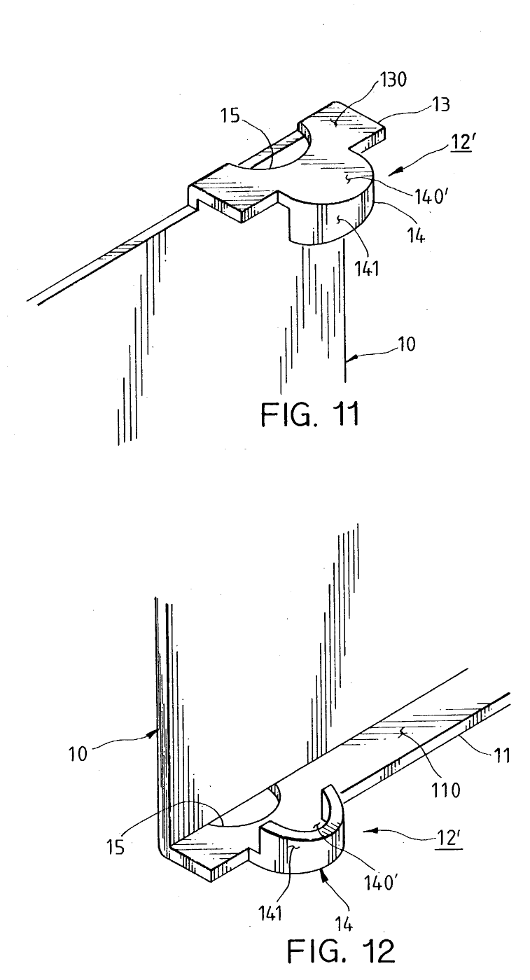

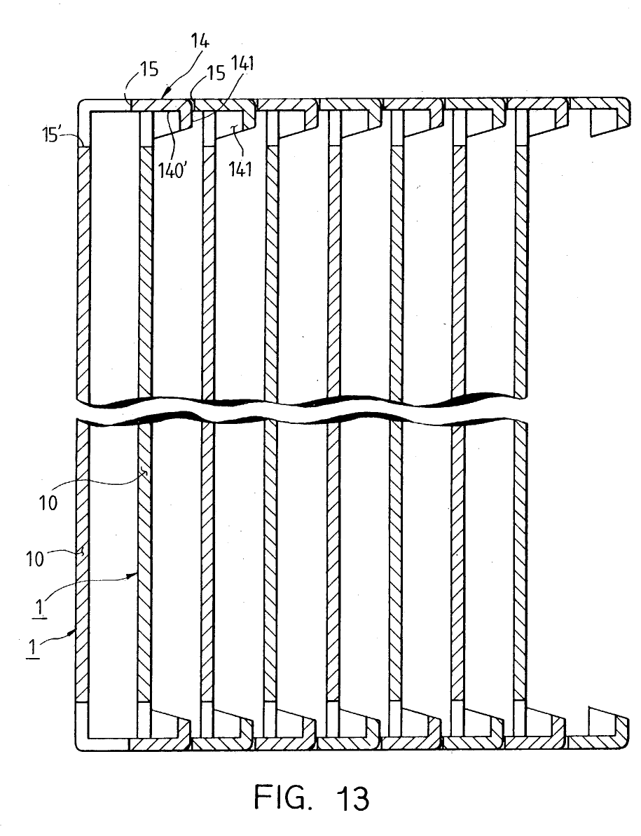

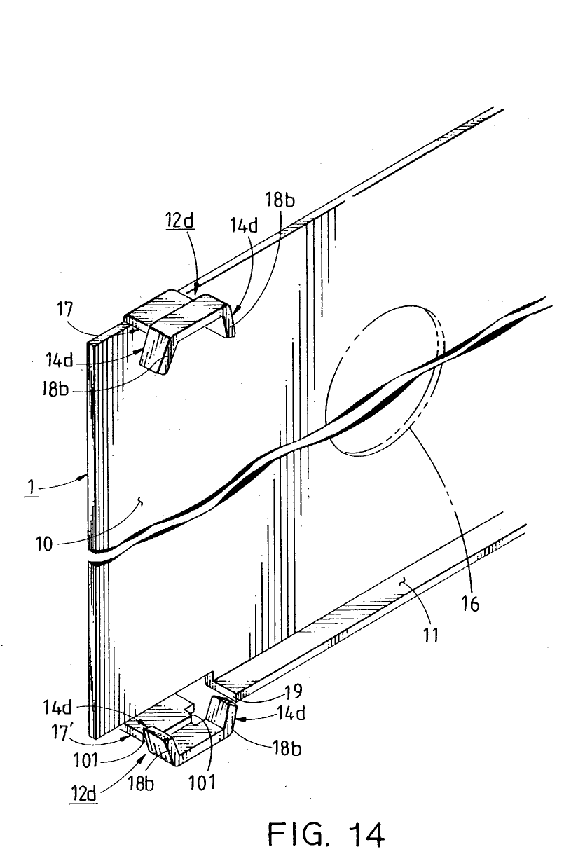

FIGS. 3˜1 and 3˜3 are perspective view of the upper connecting apparatus of FIG. 3 and FIG. 1I at the beginning stage when the material is processed by a punching and stamping machine;

FIGS. 3˜2 and 3˜4 are perspective view of the upper connecting apparatus of FIGS. 3 and 11 when a semicircular vertical folding edge of a hook takes shape by a folding machine;

FIGS. 5, 6, 5˜1, 6˜1 and FIG. 5˜2, 6˜2 are perspective view of another two embodiments of the hooks on the connecting apparatuses;

FIGS. 7 and 8 are perspective view of another embodiment of the hook on the left side of the connecting apparatus;

FIGS. 9 and 10 are perspective view of another embodiment of the hook formed on the right side of the connecting apparatus;

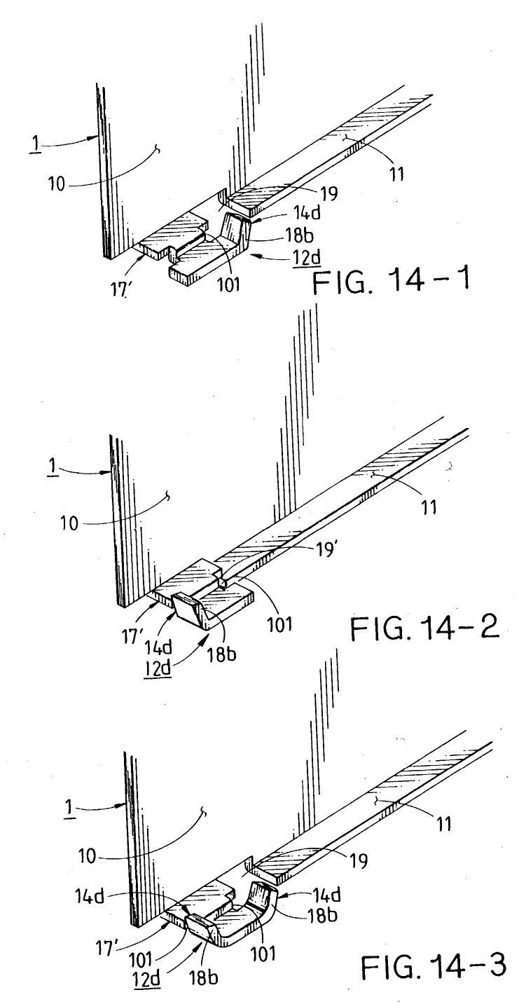

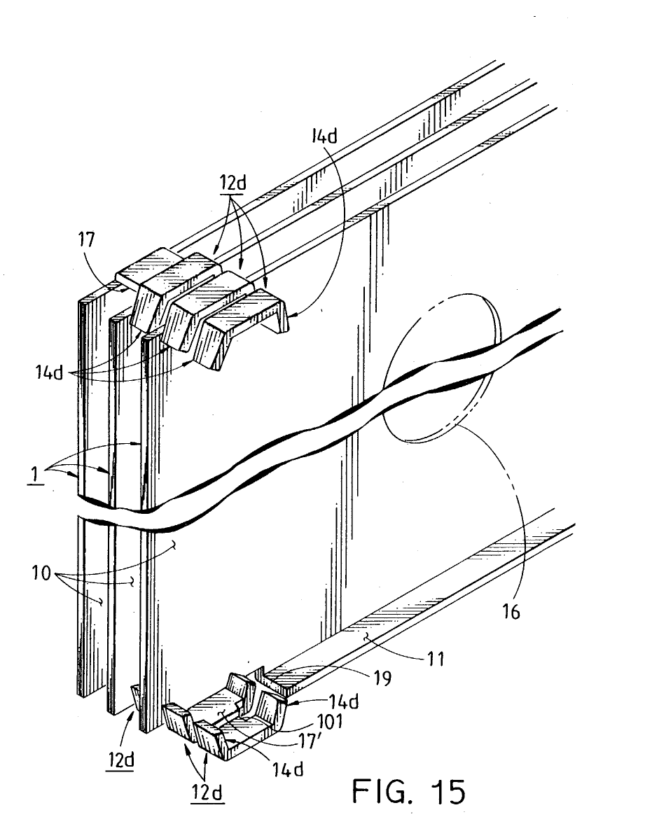

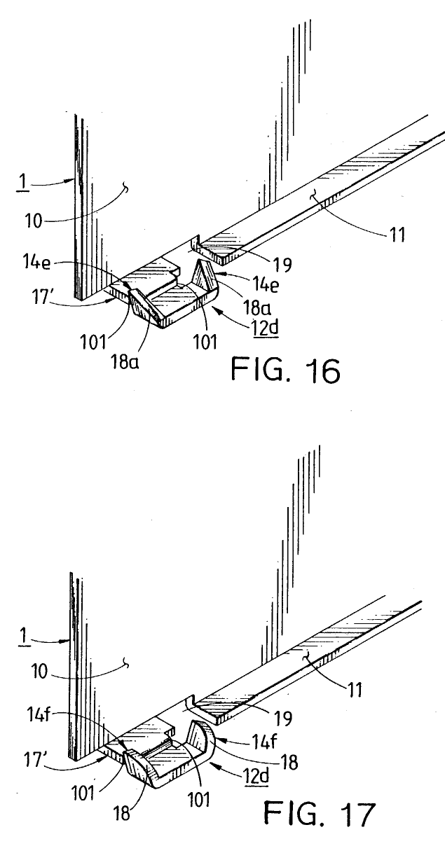

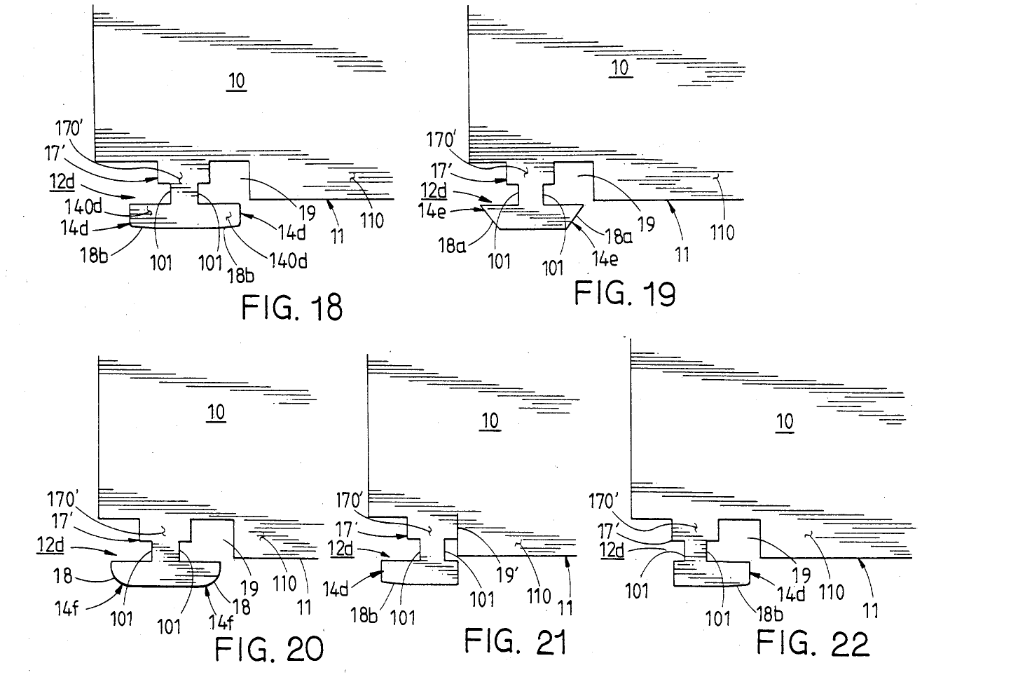

FIGS. 11 and 12 are perspective view of the connecting apparatus which is characterized by a D-shaped opening as an alternative example of FIGS. 3 and 4 respectively;

FIG. 13 is an enlarged view showing a vertical sectional drawing of an array of parallel plates when a plurality of radiation plates of FIG. 1 are assembled into a fin heat sink;

FIG. 14 is a drawing of another embodiment of one single radiation plate to illustrate the connecting apparatuses on the left part of the plate;

FIGS. 14˜1 and 14˜2 are drawings of another two embodiments of the connecting apparatus to illustrate one single hook section on the connecting apparatus at the right or left side respectively;

FIG. 14˜3 is a drawing of another embodiment of the connecting apparatus on the strips of the radiation plate.

FIG. 15 is a perspective view of three radiation plates as depicted in FIG. 14 to show the status of parallel connection;

FIGS. 16 and 17 are drawings of two better embodiments of another radiation plates to illustrate the connecting apparatuses on the left part of the plates;

FIG. 18 is a plan of FIG. 14 at the beginning stage when the material is processed by a punching and stamping machine;

FIG. 19 is a plan of FIG. 16 at the beginning stage when the material is processed by a punching and stamping machine;

FIG. 20 is a plan of FIG. 17 at the beginning stage when the material is processed by a punching and stamping machine;

FIG. 21 is a plan of FIG. 14˜2 at the beginning stage when the material is processed by a punching and stamping machine; and

FIG. 22 is a plan of FIG. 14˜1 at the beginning stage when the material is processed by a punching and stamping machine.

### DETAILED DESCRIPTION OF THE INVENTION

The present invention can be best described in detail in conjunction with the accompanied drawings as follows:

Referring to FIG. 1, it is an elevation of one single radiation plate 1 of the present invention, which is mainly comprised of an L-shaped plate body 10 and such plate body is made by punching a sheet of metallic material, such as aluminum, or further punching a plurality of holes 16 thereon, as depicted in FIG. 1˜1. The plate body 10 has disposed two or more connecting apparatuses 12 at the both sides of the upper end and lower end respectively (or disposed at the both sides of the middle section of the plate body 10 is another pair of the connecting apparatuses 12 for reinforcement.) Each of the connecting apparatus 12 at the upper end consists of a short folding edge 13, which is folded from the upper edge of the L-shaped plate body 10, and then a book 14 protrudes from each of the short folding edge 13. A strip of long level folding edge 11 is provided at the bottom of the L-shaped plate body 10, wherein two hooks 14 directly extend from the long level folding edge 11 to constitute the connecting apparatuses 12 at the both sides thereof. One semicircular aperture 15 is also a part of the connecting apparatus 12 and it is formed on the joint of the short folding edge 13 and the plate body 10 or on the joint between the long level folding edge 11 and the plate body 10.

The single radiation plate 1 of the present invention is made by means of continuous molds and dies in a process of integrated operation to punch a sheet of metallic material and shape into such heat dissipating product; therefore, when a sheet of material is manufactured into the L-shaped plate body 10 by the punching and stamping machine, punched together in the position of each connecting apparatus 12 at the upper end of the plate body 10, as shown in FIG. 3˜1, are a short folding edge body 130, one round aperture 150 and a mushroom plate 140 extending from the short folding edge body 130. Next, as illustrated in FIG. 3˜2, the mushroom plate 140 is punched and folded into a semicircular plate body 140′ and a semicircular vertical folding edge 141 to constitute the hook 14 of the connecting apparatus 12; furthermore, disposed in the position of each connecting apparatus 12 at the bottom of the plate body 10 are one aperture near the long level folding edge 11 and a mushroom plate extending from a long level folding edge body 110 (without depicting such drawing herein.) Then the above mushroom plate is also punched and folded into the semicircular plate body 140′ and the semicircular vertical folding edge. 141 to constitute the hook 14 of the connecting apparatus 12. As indicated in FIGS. 3 and 4, after each of the above-mentioned hooks 14 takes shape, the plate body 10 is folded into the long level folding edge 11 at the bottom thereof and the short folding edges 13 on the top thereof by means of continuous molds and dies in a process of integrated operation so that each of the connecting apparatus 12 is formed as an integral part thereof, which is composed of one semicircular aperture 15 and one hook 14 for fastening radiation plates.

Referring to FIG. 2, to assemble a number of single radiation plates 1 of the present invention in parallel for integrating into a heat sink, each hook 14 at the upper and bottom ends of the plate 1 is fastened with the corresponding semicircular aperture 15 of the other radiation plate 1 to the effect that every two radiation plates 1 are firmly linked with each other; the above method of linkage is taken in sequence to assemble the radiation plates 1 one by one so as to make a fin heat sink or an array of parallel plates 1, as shown in FIG. 13, for further installing with a cooling fan to dissipate heat generated from an electronic component.

During the assemblage of the radiation plates 1 into a heat sink, since each hook 14 of the preceding plate 1 is engaged with the corresponding semicircular aperture 15 on the short folding edge body 130 and long level folding edge body 110 of the following plate 1, as depicted in FIGS. 3 and 4, each semicircular opening 15′ on the L-shaped, plate body 10 serves no practical function just for the convenience of manufacturing a mold or die for punching holes in a process of integrated operation. The second embodiment of the connecting apparatus 12′ is provided by punching a D-shaped opening 150′, as indicated in FIGS. 3˜3 and 3˜4, on each of the short folding edge bodies 130 and long level folding edge body 110 respectively; likewise, the hooks 14 are formed on the said edge bodies 130 and 110 to constitute the connecting apparatus 12′ as another example of the present invention illustrated in FIG. 11 and FIG. 12. However, the identical method of linkage is taken to assemble the radiation plates 1 into a fin heat sink, so there is no need to give more details to describe the installation or the characteristics of the connecting apparatus 12′.

Furthermore, when two radiation plates 1 are linked with each other, each hook 14 of the preceding plate 1 is engaged with the corresponding semicircular aperture 15 of the following plate 1 in such a manner that the “inner part” of the semicircular vertical folding edge 141 of the former plate is fastened with the L-shaped plate body 10 of the latter plate; in addition to being shaped in the form of a semicircle, the vertical folding edge 141 of the hook 14 can be shaped in the form of an arc or inclined plane. As indicated in FIGS. 5, 6, 5˜1 and 6˜1, disposed on the semicircular plate body 140′ are oblique arcked vertical folding edges 142, 143 on the left and right sides thereof to constitute a second example of hook 14a; a third example of hook 14b is comprised of one semicircular plate body 140′ wherein an arcked vertical folding edge 142′ is formed on the left side thereof, as shown in FIGS. 7 and 8; moreover, an arcked vertical folding edge 143′ is provided on the right side of the semicircular plate body 140′ to constitute a fourth example of hook 14c, as shown in FIGS. 9 and 10. No matter what kind of hooks is formed and used to connect radiation plates 1 in parallel, there is no doubt that every two radiation plates 1 are tightly linked with each other in a convenient way by taking the above method of linkage. Besides the foregoing hooks 14, 14a, 14b and 14c, a fifth example of hook 14′a is formed as shown in FIGS. 5˜2 and 6˜2, wherein the semicircular plate body 140′ is punched into a trapezoid plate body 140″ with inclined planes on the both sides thereof and then oblique vertical folding edges 142″ and 143″ are disposed on the trapezoid plate body 140″. It is more convenient to connect radiation plates 1 by means of such hook 14′a and when a plurality of radiation plates 1 are put together into a heat sink assembly, there is less possibility of generating accumulative tolerance.

Turning to FIG. 14, it is an elevation of another embodiment of one single radiation plate 1, which is mainly comprised of an L-shaped plate body 10 and such plate body is manufactured by punching a sheet of metallic material, such as aluminum or the like; situated at the bottom of the plate body 10 is a long level folding edge 11 and further a plurality of holes 16 are provided on the plate body 10. The L-shaped plate body 10 has disposed two or more connecting apparatuses 12d at the both sides of upper end and lower end respectively or further disposed two connecting apparatuses 12d at the both sides of middle section thereof. Each connecting apparatus 12d on the L-shaped plate body 10 is manufactured as follows: the left or right upper edge of the plate body 10 is folded into an ascending-stepped strip 17 (in the shape of “ [symbol] ”) wherein the both sides of the middle part are formed indentations 101 and then the both sides of the forward part are folded downward to constitute rectangular or trapezoid hook sections 14d at an outward angle (from 90.5 at least to 179.5 degrees at most) with sloping planes 18b in FIG. 14 or with curved angle (as shown in FIG. 14˜3); the left or right bottom of the plate body 10 is folded into a descending-stepped strip 17′ (in the shape of “ [symbol] ”) wherein the both sides of the middle part are formed indentations 101 and then the both sides of the forward part are folded upward to constitute rectangular or trapezoid hook sections 14d at an outward angle (from 90.5 at least to 179.5 degrees at most) with sloping planes 18b in FIG. 14 or with curved angle (as shown in FIG. 14˜3).

Turning to FIGS. 18 and 19, the said connecting apparatus 12d of the present invention is made by means of continuous molds and dies in a process of integrated operation; at the beginning stage when the raw (rudeness) material is processed by the punching and stamping machine, the plate body 10 has disposed one T-shaped plate and one reverse T-shaped plate at each of the both sides of the upper end and lower end respectively, wherein the T-shaped plate includes an ascending-stepped strip body 170 and a hooked plate body 140d with two hook sections 14d; on the other part, the reverse T-shaped plate comprises a descending-stepped strip body 170′, a hooked plate body 140d with two hook sections 14d and a groove 19 which is a little wider than the width of the two hook sections 14d and located between the descending-stepped strip body 170′ and the long level folding edge body 110. The ascending-stepped strip body 170 and the descending-stepped strip body 170′ are bent into the shape of “ [symbol] ” and “ [symbol] ” respectively and then each hooked plate body 140d is folded into two hook sections 14d. The above bending strip bodies 170, 170′ and the long level folding edge body 110 are vertically folded into strips 17, 17′ and the long level folding edge 11 as shown in FIG. 14; hence, the whole manufacturing process is finished.

As depicted in FIG. 15, to assemble a number of single radiation plates 1 of the present invention in parallel for integrating into a heat sink, each connecting apparatus 12d with two hook sections 14d of the preceding plate 1 is fastened with the corresponding strips 17, 17′ of the following plate 1 for the purpose of fixing on the next plate body 10 through the hook sections 14d of the preceding plate 1, to thereby position the radiation plates 1 with regular distance in the horizontal direction. After an array of parallel plates is assembled, it is attached on a heat sink base by the process of tin or copper soldering to manufacture a fin heat sink for use.

For the convenience of interlocking the hook sections 14d on the connecting apparatus 12d of the preceding plate 1 with the corresponding strips 17 or 17′ on the connecting apparatus 12d of the following plate 1, the groove 19 is set between the descending-stepped strip 17′ and the long level folding edge 11 for facilitating the linkage of the hook sections 14d with the corresponding strips 17, 17′; in addition, the outer periphery of the hook section 14d is formed into a slightly sloping plane 18b to constitute the rectangular or trapezoid hook section 14d (as indicated in FIG. 14, 18) or formed into an inclined plane 18a to constitute a triangular hook section 14e (as illustrated in FIG. 16, 19) or it can be formed into an arcked plane 18 to constitute a semi-crescent hook section 14f (as depicted in FIG. 17, 20.)

Turning to FIGS. 14˜1 and 14˜2, since an assembled parallel plates 1 are fixed on a heat sink base by the process of tin or copper soldering, even one single rectangular or trapezoid hook section 14d on each of the connecting apparatus 12d is capable of tightly fastening with the strip 17 or 17′ on the other radiation plate 1 either by the left hook section 14d or the right one. However, the left hook section 14d is provided on the outside of the plate body 10, a cutting notch 19′ is formed between the descending-stepped strip body 170′ and the long level folding edge body 110 at the bottom of the L-shaped plate body 10, as shown in FIG. 21. On the contrary, the groove 19, as shown in FIG. 22, is provided between the descending-stepped strip body 170′ and the long level folding edge body 110 for facilitating each right hook section 14d of the strip body 170′ to connect with the corresponding strip 17′ on the other plate body 10. In the same way, one single triangular hook section 14e or one single semi-crescent hook section 14f on each of the connecting apparatus 12d is also capable of tightly fastening with the strip 17 or 17′ on the other radiation plate 1 and the plate body 10 has formed the groove 19 or the cutting notch 19′ respectively in the position given above.

1. A connecting apparatus of one single radiation plate consisting of:
an L-shaped plate body with a long level folding edge at the bottom thereof;
a short folding edge at the left or right side on the top of the L-shaped plate body;
two or more connecting apparatuses disposed at the both sides of the upper end of the plate body or disposed at the middle section thereof, wherein each of the connecting apparatuses includes a hook and a semicircular aperture on the joint of the short folding edge and the plate body; and
two or more connecting apparatuses disposed at the both sides of the lower end of the plate body or disposed at the middle section thereof, wherein each of the connecting apparatuses further includes a hook and a semicircular aperture on the joint between the L-shaped plate body and the long level folding edge.

2. The connecting apparatus of one single radiation plate of claim 1 wherein the said hook comprises:
a semicircular plate body with a semicircular vertical folding edge extending therefrom; or
a semicircular plate body with an arcked vertical folding edge formed on the either side thereof.

3. The connecting apparatus of one single radiation plate of claim 1 wherein the said hook further comprises:
a semicircular plate body with two oblique arcked vertical folding edges protruding from the both sides thereof; or
a trapezoid plate body with two oblique vertical folding edges disposed at the both sides thereof.

4. The connecting apparatus of one single radiation plate of claim 1 wherein the said semicircular aperture consists of:
a round aperture or a D-shaped opening formed on the short folding edge and the long level folding edge respectively.

5. A connecting apparatus of another single radiation plate developed and derivative from the claim 1 comprising:
an L-shaped plate body with a long level folding edge at the bottom thereof;
two or more connecting apparatuses disposed at the both sides of the upper end of the plate body or disposed at the middle section thereof, wherein each of the connecting apparatuses includes an ascending-stepped strip with one outward-slanted hook section folded downward on the either side thereof or with two outward-slanted hook sections folded downward on the both sides thereof, and
two or more connecting apparatuses disposed at the both sides of the lower end of the plate body or disposed at the middle section thereof, wherein each of the connecting apparatuses is composed of a descending-stepped strip with one outward-slanted hook section folded upward on the either side thereof or with two outward-slanted hook sections folded upward on the both sides thereof.

6. The connecting apparatus of the radiation plate of claim 5 wherein the parallel connection of two radiation plates is made by using one or two hook sections on each connecting apparatus of the preceding plate to link with the ascending-stepped strip or descending-stepped strip of the following plate for the purpose of tightly fastening each hook section on the preceding plate with the L-shaped plate body of the following radiation plate.

7. The connecting apparatus of the radiation plate of claim 5 wherein the hook section includes:
a rectangular or trapezoid hook section with a slightly sloping plane on the outer periphery thereof;
a triangular hook section with an inclined plane on the outer periphery thereof; or
a semi-crescent hook section with an arcked plane on the outer periphery thereof.

8. The connecting apparatus of the radiation plate of claim 5 wherein a groove is provided between the long level folding edge at the bottom of the plate body and the descending-stepped strip for facilitating each hook section at the inner side of the descending-stepped strip to connect with the corresponding strip on the other radiation plate and moreover a cutting notch is provided therebetween for facilitating each hook section at the outside of the descending-stepped strip to connect therewith.

9. The connecting apparatus of the radiation plate of claim 1 or 5 wherein the radiation plate has alternatively disposed a plurality of holes on the L-shaped plate body to promote heat dissipation efficiency.

10. The connecting apparatus of the radiation plate Of claim 5, 8 or 7 wherein the hook section is outward-slanted with a curved angle.

11. The connecting apparatus of the radiation plate of claim 5, 8 or 7 wherein the hook section is folded outward at an angle from 90.5 degrees at least to 179.5 degrees at most.
